(19) United States
(12) Patent Application Publication
(10) Pub. No.: US 2025/0365954 A1
(43) Pub. Date: Nov. 27, 2025

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Qingyi Huang, Wuhan (CN); Zhen Pan, Wuhan (CN)

(21) Appl. No.: 18/735,931

(22) Filed: Jun. 6, 2024

Related U.S. Application Data
(63) Continuation of application No. PCT/CN2024/094438, filed on May 21, 2024.

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80895; H01L 2224/80896; H01L 2924/1431; H01L 2924/14511

(57) ABSTRACT

Three-dimensional (3D) memory devices and fabricating methods thereof are disclosed. In certain aspects, a disclosed 3D memory device can comprise a plurality of memory regions each comprising a memory stack and a plurality of channel structures vertically extending through the memory stack, a spacer region between the plurality of memory regions, comprising a dielectric stack located between adjacent memory stacks, and a patterned conductive layer on the memory stacks and the dielectric stack. The patterned conductive layer comprises interconnection structures in the memory regions and coupled with the plurality of channel structures, and dummy interconnection structures on the dielectric stack in the spacer region and arranged in a staggered manner.

### CROSS-REFERENCE TO RELATED APPLICATIONS

This application is a continuation of International Application No. PCT/CN2024/094438, filed on May 21, 2024, which is hereby incorporated by reference in its entirety.

### TECHNICAL FIELD

The present disclosure generally relates to the field of semiconductor technology, and more particularly, to three-dimensional (3D) memory devices and fabricating methods thereof.

### BACKGROUND

With the continuous rise and development of artificial intelligence (AI), big data, Internet of Things (IoTs), mobile devices and communications, cloud storage, etc., the demand for memory capacity is growing in an exponential way. Compared with other non-volatile memories, NAND memory has many advantages, such as high integration, low power consumption, fast programming/erasing speed, good reliability, low cost, etc., and thus has gradually become the mainstream semiconductor memory in the industry.

Planar NAND memory cells are scaled to smaller sizes by improving process technology, circuit design, programming algorithm, and fabrication process. However, as feature sizes of the memory cells approach a lower limit, the planar process and fabrication techniques become challenging and costly. As a result, memory density for planar memory cells approaches an upper limit.

A three-dimensional (3D) NAND memory architecture can address the density limitation in planar memory cells. The 3D memory architecture includes a memory array and periphery devices for controlling signals to and from the memory array.

### SUMMARY

One aspect of the present disclosure provides a semiconductor device, comprising: a plurality of memory regions each comprising a memory stack and a plurality of channel structures vertically extending through the memory stack; a spacer region between the plurality of memory regions, comprising a dielectric stack located between adjacent memory stacks; and a patterned conductive layer on the memory stacks and the dielectric stack, comprising: interconnection structures in the memory regions and coupled with the plurality of channel structures, and dummy interconnection structures on the dielectric stack in the spacer region and arranged in a staggered manner.

In some implementations, the semiconductor device further comprises: a semiconductor layer in the memory regions covering the memory stacks and in contact with the plurality of channel structures; wherein each interconnection structure includes a via structure extending through an insulating layer and in contact with the semiconductor layer, and each dummy interconnection structure is above the insulating layer.

In some implementations, each dummy interconnection structure extends along a lateral direction and comprises a first end in contact with the interconnection structures and a second end without in contact with the interconnection structures.

In some implementations, the dummy interconnection structures comprise: first dummy interconnection structures in contact with first interconnection structures in a first memory region and having a first distance from second interconnection structures in a second memory region adjacent to the first memory region; and second dummy interconnection structures in contact with the second interconnection structures in a second memory region and having the first distance from the first interconnection structures in the first memory region; wherein the first dummy interconnection structures and the second dummy interconnection structures are positioned alternatively.

In some implementations, a first radio between a length of one first dummy interconnection structure and the first distance is in a range between about 1 and about 100.

In some implementations, a second radio between a width of one first dummy interconnection structure and a second distance from the one first dummy interconnection structure to an adjacent second dummy interconnection structure is in a range between about 1 and about 50.

In some implementations, the dummy interconnection structures comprises: a central dummy interconnection structure located in a central spacer region between four adjacent memory regions, and comprising a first branch extending along a first lateral direction and a second branch extending along a second lateral direction different from the first lateral direction.

In some implementations, each dummy interconnection structure comprises a first branch extending along a first lateral direction and a plurality of second branches each extending along a second lateral direction different from the first lateral direction; and the second branches of two adjacent dummy interconnection structures are positioned alternatively along the first lateral direction.

In some implementations, an angle between each dummy interconnection structure and an edge of one memory region in a lateral plane is less than 90 degrees.

In some implementations, each dummy interconnection structure comprises a first section extending along a first lateral direction and a second section extending along a second lateral direction different from the first lateral direction; and an angle between the first section and the second section is larger than 90 degrees.

In some implementations, each dummy interconnection structure comprises: a first section and a third section each extending along a first lateral direction; and a second section between the first section and the third section, and extending along a second lateral direction different from the lateral first direction.

In some implementations, the semiconductor device further comprises: a periphery circuit comprising transistors coupled with the plurality of channel structures.

Another aspect of the present disclosure provides a semiconductor device, comprising: a first memory plane comprising: a first memory stack, first channel structures vertically extending through the first memory stack, and first interconnection structures on the first memory stack and coupled with the first channel structures; a second memory plane located at a lateral side of the first memory plane, comprising: a second memory stack, second channel structures vertically extending through the second memory stack, and second interconnection structures on the second memory stack and coupled with the first channel structures; a spacer region between the first memory plane and the second memory planes, comprising: a dielectric stack located laterally between the first memory stack and the second memory stack, first dummy interconnection structures extending along a first lateral direction on the dielectric stack and in contact with the first interconnection structures, and second dummy interconnection structures along the first lateral direction on the dielectric stack and in contact with the second interconnection structure, wherein the first dummy interconnection structures and the second dummy interconnection structures are alternatively arranged along a second lateral direction.

Another aspect of the present disclosure provides a method of forming a semiconductor device, comprising: forming a plurality of memory regions each comprising a memory stack and a plurality of channel structures vertically extending through the memory stack, and forming a spacer region between the plurality of memory regions and comprising dielectric stack portions located between adjacent memory stacks; and forming a patterned conductive layer on the memory stacks and the dielectric stack, comprising: forming interconnection structures in the memory regions and coupled with the plurality of channel structures, and forming dummy interconnection structures on the dielectric stack in the spacer region and arranged in a staggered manner.

In some implementations, the method further comprises: forming a semiconductor layer in the memory regions covering the memory stacks and in contact with first ends of the plurality of channel structures; and forming an insulating layer in the space region and the plurality of memory regions to cover the dielectric stack portions and the semiconductor layer.

In some implementations, forming the patterned conductive layer comprises: forming openings in the insulating layer to expose the semiconductor layer; forming a conductive layer on the insulating layer and in the openings to be in contact with the semiconductor layer; and patterning the conductive layer to form the patterned conductive layer.

In some implementations, the method further comprises: forming a dielectric stack including alternating dielectric layers and sacrificial layers; forming the plurality of channel structures vertically extending through the dielectric stack in the plurality of memory regions; replacing portions of the sacrificial layers in the plurality of memory regions with conductive layers to convert the dielectric stack in the plurality of memory regions into the memory stacks; and remaining the portions of the dielectric stack in the spacer region between the plurality of memory regions.

In some implementations, the method further comprises: before forming the semiconductor layer, forming a first interconnection layer in contact with second ends of the plurality of channel structures opposite to the first ends; forming a peripheral circuit comprising transistors and a second interconnection layer coupled with the transistors; and bonding the second interconnection layer with the first interconnection layer to couple the transistors with the plurality of channel structures.

In some implementations, the method further comprises: forming a plurality of dummy channel structures vertically extending through the dielectric stack in the spacer region; and forming a block layer on the dummy channel structures in the spacer region; wherein the semiconductor layer extends into the spacer region and is separated from the dummy channel structures by the block layer.

In some implementations, patterning the conductive layer comprises: forming each dummy interconnection structure extending along a lateral direction and comprising a first end in contact with the interconnection structures and a second end without in contact with the interconnection structures.

In some implementations, patterning the conductive layer comprises: forming first dummy interconnection structures in contact with first interconnection structures in a first memory region and having a first distance from second interconnection structures in a second memory region adjacent to the first memory region; and forming second dummy interconnection structures in contact with the second interconnection structures in a second memory region and having the first distance from the first interconnection structures in the first memory region; wherein the first dummy interconnection structures and the second dummy interconnection structures are positioned alternatively.

In some implementations, patterning the conductive layer comprises: forming the dummy interconnection structures in a corner spacer region between four plurality of memory regions each comprising a first branch extending along a first lateral direction and a second branch extending along a second lateral direction different from the first lateral direction.

In some implementations, patterning the conductive layer comprises: forming each dummy interconnection structure comprising a first branch extending along a first lateral direction and a plurality of second branches each extending along a second lateral direction different from the first lateral direction; wherein the second branches of two adjacent dummy interconnection structures are positioned alternatively along the first lateral direction.

In some implementations, patterning the conductive layer comprises: forming an angle between each dummy interconnection structure and an edge of one memory region in a lateral plane less than 90 degrees.

In some implementations, patterning the conductive layer comprises: forming each dummy interconnection structure comprising a first section extending along a first lateral direction and a second section extending along a second lateral direction different from the first lateral direction; wherein an angle between the first section and the second section is larger than 90 degrees.

In some implementations, patterning the conductive layer comprises: forming each dummy interconnection structure comprising a first section and a third section each extending along a first lateral direction, and a second section between the first section and the third section, and extending along a second lateral direction different from the first lateral direction.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a cross-section of an exemplary 3D memory device, according to some aspects of the present disclosure.

FIG. 2 illustrates a schematic circuit diagram of an exemplary memory device, according to some aspects of the present disclosure.

FIG. 3 illustrates a schematic circuit diagram of an exemplary memory device, according to some aspects of the present disclosure.

FIG. 4 illustrates a schematic diagram of a cross-section of an exemplary 3D memory device, according to some aspects of the present disclosure.

FIG. 5A illustrates a schematic diagram of an exemplary 3D memory device in a top view, according to some aspects of the present disclosure.

FIG. 5B illustrates a schematic diagram of a portion of the exemplary 3D memory device shown in FIG. 6A in an enlarged top view, according to some aspects of the present disclosure.

FIG. 6A illustrates a schematic diagram of an exemplary 3D memory device in a top view, according to some aspects of the present disclosure.

FIG. 6B illustrates a schematic diagram of an exemplary 3D memory device in a top view, according to some aspects of the present disclosure.

FIG. 6C illustrates a schematic diagram of an exemplary 3D memory device in a top view, according to some aspects of the present disclosure.

FIG. 6D illustrates a schematic diagram of an exemplary 3D memory device in a top view, according to some aspects of the present disclosure.

FIG. 7 illustrates a block diagram of an exemplary system having a 3D memory device, according to some aspects of the present disclosure.

FIG. 8A illustrates a diagram of an exemplary memory card having a 3D memory device, according to some aspects of the present disclosure.

FIG. 8B illustrates a diagram of an exemplary solid-state drive (SSD) having a 3D memory device, according to some aspects of the present disclosure.

FIG. 9 illustrates a flow diagram of an exemplary method for forming a 3D memory device, according to s some aspects of the present disclosure.

FIGS. 10A-10E illustrate schematic cross-sectional views of an exemplary 3D memory device at certain fabricating stages of the method shown in FIG. 8, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contact structures are formed) and one or more dielectric layers.

As semiconductor technology advances, three-dimensional (3D) memory devices, such as 3D NAND memory devices, keep scaling more oxide/nitride (ON) layers of the memory cell array. With the increase of the number of array layers of the 3D architecture, the complementary metal-oxide semiconductor (CMOS) periphery circuit needs more complex and size scaling. For example, a complementary metal-oxide-semiconductor wafer (“CMOS wafer” hereinafter) is bonded with a memory cell array wafer (“array wafer” hereinafter) to form a framework of the 3D memory device. The memory cell array wafer can include multiple memory cell arrays arranged in an array form. The semiconductor structures in the spacer regions between adjacent memory cell arrays can cause uneven topography, thereby reducing memory device strength. Accordingly, new 3D memory devices having novel structure design and fabricating methods thereof are provided to address such issues.

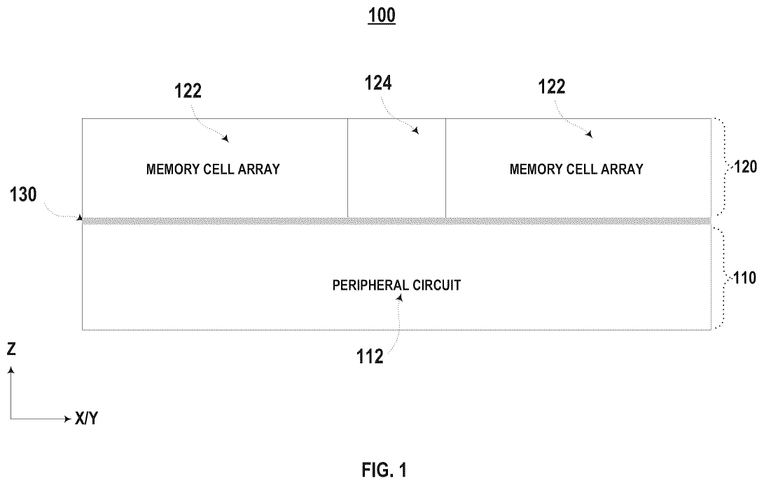

FIG. 1 illustrates a schematic view of a cross-section of a 3D memory device 100, according to some aspects of the present disclosure. 3D memory device 100 represents an example of a bonded chip. In some implementations, at least some of the components of 3D memory device 100 (e.g., first wafer/first semiconductor structure 110 and second wafer/second semiconductor structure 120 as shown in FIG. 1) are formed separately on different substrates in parallel and then jointed to form a bonded chip (a process referred to herein as a “parallel process”).

It is noted that X/Y and Z axes are added in FIG. 1 to further illustrate the spatial relationships of the components of a semiconductor device. A substrate of a semiconductor device, e.g., 3D memory device 100, includes two lateral surfaces (e.g., a top surface and a bottom surface) extending laterally in the x-direction (e.g., word line direction) and the y-direction (e.g., bit line direction). As used herein, whether one component (e.g., a layer or a device) is “on,” “above,” or “below” another component (e.g., a layer or a device) of a semiconductor device is determined relative to the substrate of the semiconductor device in the z-direction (the vertical direction or thickness direction) when the substrate is positioned in the lowest plane of the semiconductor device in the z-direction. The same notion for describing the spatial relationships is applied throughout the present disclosure.

As shown in FIG. 1, 3D memory device 100 can include a first semiconductor structure 110 including periphery circuits 112 and a second semiconductor structure 120 including memory cell arrays 122. That is, the memory cell arrays 122 and the periphery circuits 112 of the memory cell arrays 122 can be separated into at least two other semiconductor structures (e.g., 110 and 120 in FIG. 1).

In some implementations, the periphery circuits 112 can be coupled with the memory cell arrays 122 to perform read/program (write)/erase operations of the memory cell arrays 122. The periphery circuits 112 (a.k.a. control and sensing circuits) can include any suitable digital, analog, and/or mixed-signal circuits used for facilitating the operations of the memory cell arrays 122. For example, the periphery circuits 112 can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The periphery circuits 112 in the first semiconductor structure 110 can use CMOS technology, e.g., which can be implemented with logic processes in any suitable technology nodes.

In some implementations, the second semiconductor structure 120 can include multiple memory cell arrays 122 that are separated by a spacer region 124. Each memory cell array 122 in the second semiconductor structure 120 can include an array of memory cells, such as an array of NAND Flash memory cells. For ease of description, a NAND Flash memory cell array may be used as an example for describing the memory cell array 122 in the present disclosure. But it is understood that the memory cell arrays 122 are not limited to NAND Flash memory cell arrays and may include any other suitable types of memory cell arrays, such as NOR Flash memory cell arrays, phase change memory (PCM) cell arrays, resistive memory cell arrays, magnetic memory cell arrays, spin transfer torque (STT) memory cell arrays, to name a few. In some implementations, the multiple memory cell arrays 122 can be the same type or be different types.

In some implementations, each memory cell array 122 can be a NAND Flash memory device in which memory cells are provided in the form of an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes a certain number of NAND memory cells, each of which includes a floating-gate transistor or a charge-trap transistor. NAND memory cells can be organized into pages or fingers, which are then organized into blocks in which each NAND memory cell is coupled to a bit line (BL) and a word line (WL). In some implementations, a memory plane contains a certain number of blocks that are coupled through the same bit line. First semiconductor structure 110 can include one or more memory planes.

As shown in FIG. 1, the first semiconductor structure 110 and the second semiconductor structure 120 are stacked in the vertical direction (the z-direction). In some implementations, the first semiconductor structure 110 and the second semiconductor structure 120 are bonded together. Thus, the 3D memory device 100 further includes a bonding interface 130 vertically between the first semiconductor structure 110 and the second semiconductor structure 120. Bonding interface 130 can be an interface between two semiconductor structures formed by any suitable bonding technologies as described below in detail, such as hybrid bonding, anodic bonding, fusion bonding, transfer bonding, adhesive bonding, and eutectic bonding, to name a few.

The first semiconductor structure 110 and the second semiconductor structure 120 can be fabricated separately (and in parallel in some implementations) by the parallel process, such that the thermal budget of fabricating one of the first and second semiconductor structures 110 and 120 does not limit the processes of fabricating another one of the first and second semiconductor structures 110 and 120. Moreover, a large number of interconnects (e.g., bonding contact structures and/or inter-layer vias (ILVs)/through substrate vias (TSVs)) can be formed across the bonding interface 130 to make direct, short-distance (e.g., micron- or submicron-level) electrical connections between the first and second semiconductor structures 110 and 120, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer among the memory cell arrays 122 and the different periphery circuits 112 in the first and second semiconductor structures 110 and 120 can be performed through the interconnects (e.g., bonding contact structures and/or ILVs/TSVs) across bonding interface 130. By vertically integrating the first and second semiconductor structures 110 and 120, the chip size can be reduced, and the memory cell density can be increased.

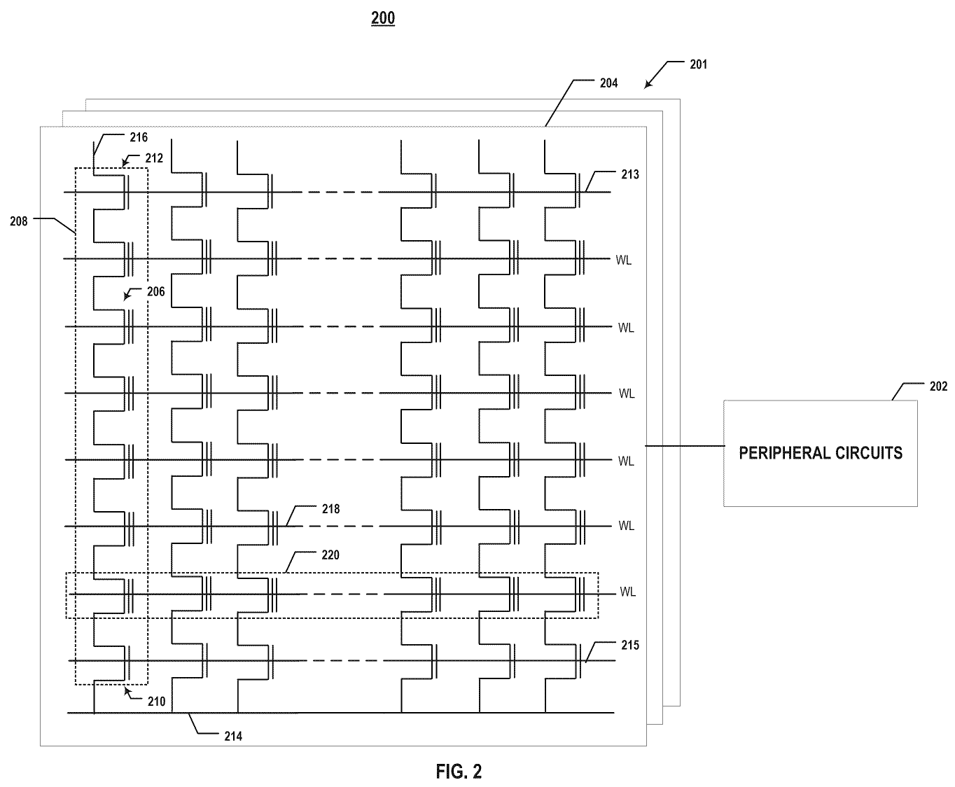

FIG. 2 illustrates a schematic circuit diagram of a memory device 200, according to some aspects of the present disclosure. Memory device 200 can include multiple memory cell arrays 201 and periphery circuits 202 coupled to the memory cell arrays 201. 3D memory device 100 may be an example of memory device 200 in which periphery circuits 202 may be included in the first and second semiconductor structures 110 and 120. Memory cell arrays 201 can be NAND Flash memory cell arrays in which memory cells 206 are provided in the form of arrays of NAND memory strings 208 each extending vertically above a substrate (not shown). In some implementations, each NAND memory string 208 includes a plurality of memory cells 206 coupled in series and stacked vertically. Each memory cell 206 can hold a continuous, analog value, such as an electrical voltage or charge, that depends on the number of electrons trapped within a region of memory cell 206. Each memory cell 206 can be either a floating gate type of memory cell including a floating-gate transistor or a charge trap type of memory cell including a charge-trap transistor.

In some implementations, each memory cell 206 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 2, each NAND memory string 208 can include a source select gate (SSG) transistor 210 at its source end and a drain select gate (DSG) transistor 212 at its drain end. SSG transistor 210 and DSG transistor 212 can be configured to activate selected NAND memory strings 208 (columns of the array) during read and program operations. In some implementations, SSG transistors 210 of NAND memory strings 208 in the same block 204 are coupled through a same source line (SL) 214, e.g., a common SL, for example, to the ground. DSG transistor 212 of each NAND memory string 208 is coupled to a respective bit line 216 from which data can be read or programmed via an output bus (not shown), according to some implementations. In some implementations, each NAND memory string 208 is configured to be selected or deselected by applying a select voltage (e.g., above the threshold voltage of DSG transistor 212) or a deselect voltage (e.g., 0 V) to respective DSG transistor 212 through one or more DSG lines 213 and/or by applying a select voltage (e.g., above the threshold voltage of SSG transistor 210) or a deselect voltage (e.g., 0 V) to respective SSG transistor 210 through one or more SSG lines 215.

As shown in FIG. 2, NAND memory strings 208 can be organized into multiple blocks 204, each of which can have a common source line 214. In some implementations, each block 204 is the basic data unit for erase operations, i.e., all memory cells 206 on the same block 204 are erased at the same time. Memory cells 206 of adjacent NAND memory strings 208 can be coupled through word lines 218 that select which row of memory cells 206 is affected by read and program operations. In some implementations, each word line 218 is coupled to a page 220 of memory cells 206, which is the basic data unit for program and read operations. The size of one page 220 in bits can correspond to the number of NAND memory strings 208 coupled by word line 218 in one block 204. Each word line 218 can include a plurality of control gates (gate electrodes) at each memory cell 206 in respective page 220 and a gate line coupling the control gates. In some implementations, multiple blocks 204 can be organized into a memory plane (not shown), which forms one memory cell array 122 as shown in FIG. 1, and multiple memory planes can be formed on a same die, which constitute the second semiconductor structure 120 as shown in FIG. 1.

Referring to FIG. 2, periphery circuits 202 can be coupled to memory cell arrays 201 through bit lines 216, word lines 218, source lines 214, SSG lines 215, and DSG lines 213. As described above, periphery circuits 202 can include any suitable circuits for facilitating the operations of memory cell arrays 201 by applying and sensing voltage signals and/or current signals through bit lines 216 to and from each target memory cell 206 through word lines 218, source lines 214, SSG lines 215, and DSG lines 213. Periphery circuits 202 can include various types of periphery circuits formed using CMOS technologies.

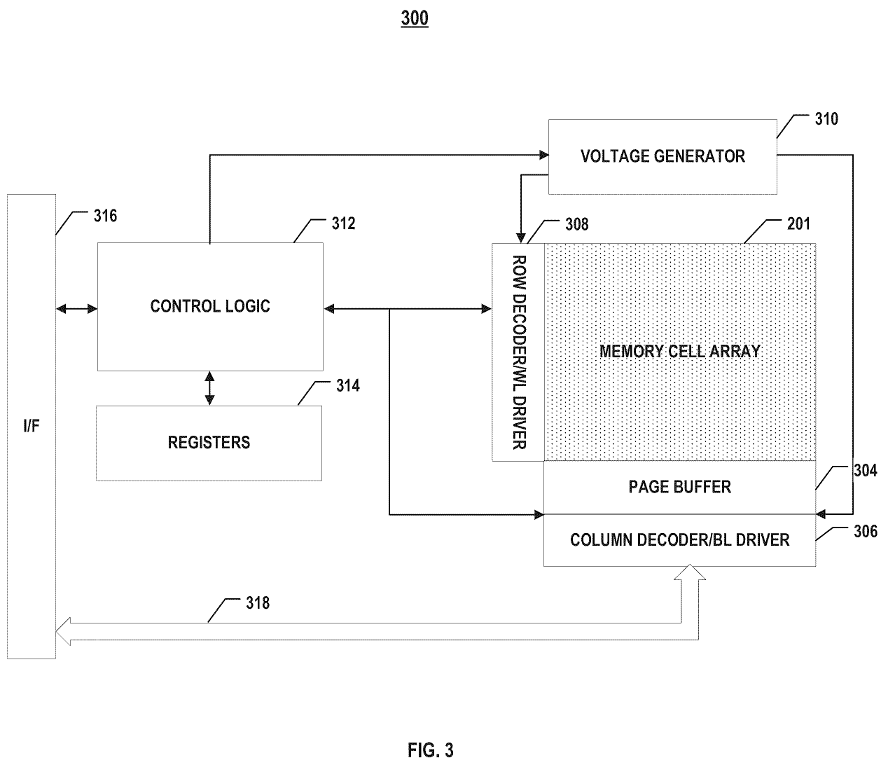

For example, FIG. 3 illustrates memory device 300 including a memory cell array 201 and various exemplary periphery circuits 202. Periphery circuits 202 include a page buffer 304, a column decoder/bit line driver 306, a row decoder/word line driver 308, a voltage generator 310, control logic 312, registers 314, an interface (I/F) 316, and a data bus 318. It is understood that in some examples, additional periphery circuits 202 may be included as well. It is noted that FIG. 3 shows only one memory cell array 201 for simplicity, but memory device 300 comprises multiple memory cell arrays 201 and corresponding periphery circuits 202 for each memory cell array 201.

Page buffer 304 can be configured to buffer data read from or programmed to memory cell array 201 according to the control signals of control logic 312. In one example, page buffer 304 may store one page of program data (write data) to be programmed into one page 220 of the memory cell array 201. In another example, page buffer 304 also performs program verify operations to ensure that the data has been properly programmed into memory cells 206 coupled to selected word lines 218.

Row decoder/word line driver 308 can be configured to be controlled by control logic 312 and select block 204 of the memory cell array 201 and a word line 218 of selected block 204. Row decoder/word line driver 308 can be further configured to drive the memory cell array 201. For example, row decoder/word line driver 308 may drive memory cells 206 coupled to the selected word line 218 using a word line voltage generated from voltage generator 310.

Column decoder/bit line driver 306 can be configured to be controlled by control logic 312 and select one or more 3D NAND memory strings 208 by applying bit line voltages generated from voltage generator 310. For example, column decoder/bit line driver 306 may apply column signals for selecting a set of N bits of data from page buffer 304 to be output in a read operation.

Control logic 312 can be coupled to each periphery circuit 202 and configured to control operations of periphery circuits 202. Registers 314 can be coupled to control logic 312 and include status registers, command registers, and address registers for storing status information, command operation codes (OP codes), and command addresses for controlling the operations of each periphery circuit 202.

Interface 316 can be coupled to control logic 312 and configured to interface the memory cell array 201 with a memory controller (not shown). In some implementations, interface 316 acts as a control buffer to buffer and relay control commands received from the memory controller and/or a host (not shown) to control logic 312 and status information received from control logic 312 to the memory controller and/or the host. Interface 316 can also be coupled to page buffer 304 and column decoder/bit line driver 306 via data bus 318 and act as an I/O interface and a data buffer to buffer and relay the program data received from the memory controller and/or the host to page buffer 304 and the read data from page buffer 304 to the memory controller and/or the host. In some implementations, interface 316 and data bus 318 are parts of an I/O circuit of periphery circuits 202.

Voltage generator 310 can be configured to be controlled by control logic 312 and generate the word line voltages (e.g., read voltage, program voltage, pass voltage, local voltage, and verification voltage) and the bit line voltages to be supplied to memory cell array 201. In some implementations, voltage generator 310 is part of a voltage source that provides voltages at various levels of different periphery circuits 202 as described below in detail. Consistent with the scope of the present disclosure, in some implementations, the voltages provided by voltage generator 310, for example, to row decoder/word line driver 308, column decoder/bit line driver 306, and page buffer 304 are above certain levels that are sufficient to perform the memory operations.

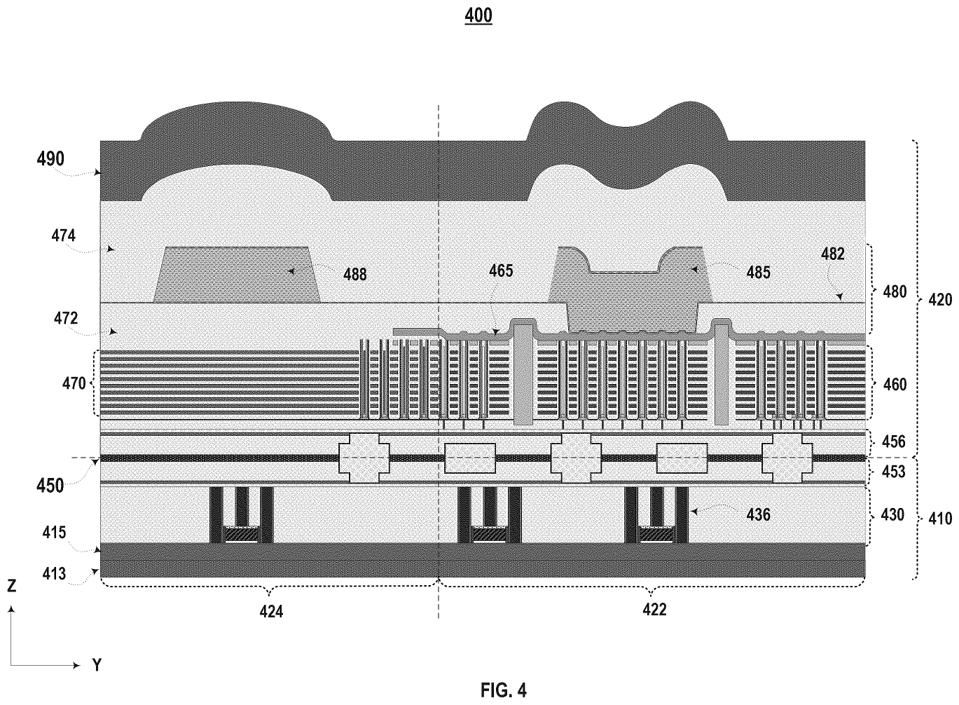

FIG. 4 illustrates a side view of a cross-section of an exemplary 3D memory device 400, according to some aspects of the present disclosure. It is noted that X and Z axes are included in FIG. 4 to further illustrate the spatial relationship of the components in 3D memory device 400. As shown in FIG. 4, in some implementations, 3D memory device 400 is a bonded chip including a first semiconductor structure 410 and a second semiconductor structure 420 stacked over first semiconductor structure 410. First and second semiconductor structures 410 and 420 are jointed at a bonding interface 450 therebetween, according to some implementations.

As shown in FIG. 4, the first semiconductor structure 410 can include substrate 413 and semiconductor layer 415. Substrate 413 can be any suitable substrate, such as a semiconductor substrate or a non-semiconductor substrate. Semiconductor layer 415 can include silicon (e.g., single crystalline silicon, c-Si), silicon germanium (SiGe), gallium arsenide (GaAs), germanium (Gc), silicon-on-insulator (SOI), or any other suitable semiconductor materials. In some implementations, first semiconductor structure 410 of 3D memory device 400 can include a device layer 430 on semiconductor layer 415. In some implementations, device layer 430 comprises a plurality of transistors 436 that form one or more periphery circuits described above. In some implementations, isolation regions (e.g., shallow trench isolations (STIs), not shown) and doped regions (e.g., source regions and drain regions of the transistors) can be formed in semiconductor layer 415.

As shown in FIG. 4, the second semiconductor structure 420 can be bonded on top of the first semiconductor structure 410 in a face-to-face manner at bonding interface 450. In some implementations, bonding interface 450 is a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 450 is the place at which first semiconductor structure 410 and second semiconductor structure 420 are met and bonded.

In some implementations, the first semiconductor structure 410 of 3D memory device 400 can further include a first bonding layer 453 at the bonding interface 450. The second semiconductor structure 420 of 3D memory device 100 can include a second bonding layer 456 bonded with the first bonding layer 453 of the first semiconductor structure 410 at bonding interface 450. The first and second bonding layers 453 and 456 can include a plurality of bonding contact structures and dielectrics electrically isolating the bonding contact structures. Bonding contact structures can include conductive materials including, but not limited to, W, Co, Cu, Al, silicides, or any combination thereof. The remaining areas of the first and second bonding layers 453 and 456 can be formed with dielectrics including, but not limited to, silicon oxide, silicon nitride, silicon oxynitride, low-k dielectrics, or any combination thereof. The bonding contact structures and surrounding dielectrics in the first and second bonding layers 453 and 456 can be used for hybrid bonding. The bonding contact structures of the first bonding layer 453 are in contact with the bonding contact structures of the second bonding layer at bonding interface 450, according to some implementations.

In some implementations, the first semiconductor structure 410 of 3D memory device 400 further includes a first interconnect layer (not shown) between the device layer 430 and coupled with the first bonding layer 453, and the second semiconductor structure 420 of 3D memory device 400 further includes a second interconnect layer (not shown) between the second bonding layer 456 and the memory cell arrays. The first and second interconnect layers can include a plurality of interconnects (also referred to herein as contact structures), including lateral interconnect lines and vertical interconnect access (VIA) contact structures, to transfer electrical signals between the periphery circuits and the memory cell arrays. As used herein, the term interconnects can broadly include any suitable types of interconnects, such as middle-end-of-line (MEOL) interconnects and back-end-of-line (BEOL) interconnects. The first and second interconnect layers can further include one or more interlayer dielectric (ILD) layers (a.k.a. intermetal dielectric (IMD) layers) in which the interconnect lines and VIA contact structures can form. That is, the first and second interconnect layers can include interconnect lines and VIA contact structures in multiple ILD layers. The interconnect lines and VIA contact structures in the first and second interconnect layers can include conductive materials including, but not limited to, tungsten (W), cobalt (Co), copper (Cu), aluminum (Al), silicides, or any combination thereof. The ILD layers in the first and second interconnect layers can include dielectric materials including, but not limited to, silicon oxide, silicon nitride, silicon oxynitride, low dielectric constant (low-K) dielectrics, or any combination thereof.

In some implementations, the second semiconductor structure 420 of the 3D memory device 400 can include a plurality of memory regions 422 (also referred to as array regions or core regions) and spacer regions 424 between adjacent memory regions 422. In each memory region 422, the second semiconductor structure 420 can include a NAND Flash memory device in which the array of memory cells can be provided in the form of an array of NAND memory strings. Each NAND memory string can include a respective channel structure extending vertically through a memory stack 460. The memory stack 460 can include a plurality of pairs each including a stack conductive layer and a stack dielectric layer. In some implementations, the stack conductive layers can include any suitable conductive materials (i.e., tungsten, etc.), and the stack dielectric layers can include any suitable insulating materials (i.e., silicon oxide, etc.). The interleaved stack conductive layers and stack dielectric layers are part of memory stack 460. The number of the pairs of stack conductive layers and stack dielectric layers in the memory stack 460 determines the number of memory cells in 3D memory device 400. It is understood that in some implementations, the memory stack 460 may have a staircase structure, which includes a plurality of memory decks stacked over one another. The numbers of the pairs of stack conductive layers and stack dielectric layers in each memory deck can be the same or different.

Memory stack 460 can include a plurality of interleaved stack conductive layers and stack dielectric layers. Stack conductive layers and stack dielectric layers in memory stack 460 can alternate in the vertical direction. In other words, except for the ones at the top or bottom of the memory stack 460, each stack conductive layer can be adjoined by two stack dielectric layers on both sides, and each stack dielectric layer can be adjoined by two stack conductive layers on both sides. The stack conductive layers can include conductive materials including, but not limited to, W, Co, Cu, Al, polysilicon, doped silicon, silicides, or any combination thereof. Each stack conductive layer can include a gate electrode (gate line) surrounded by an adhesive layer and a gate dielectric layer. The gate electrode of stack conductive layer can extend laterally as a word line, ending at one or more staircase structures of memory stack. The stack dielectric layers can include dielectric materials including, but not limited to, silicon oxide, silicon nitride, silicon oxynitride, or any combination thereof.

In some implementations, each channel structure can have a cylinder shape (e.g., a pillar shape), and can extend vertically through interleaved stack conductive layers and stack dielectric layers of the memory stack 460. Each channel structure includes a channel hole filled with a composite memory layer, a channel layer, and a filling structure that are arranged radially from the center toward the outer surface of the pillar in this order, according to some implementations. The filling structure can include dielectric materials, such as silicon oxide, and/or an air gap. The composite memory layer can radially circumscribe the channel layer along the lateral direction. The composite memory layer can be formed laterally between the channel layer and the memory stack 460. In some implementations, the channel layer includes silicon, such as amorphous silicon, polysilicon, or single crystalline silicon. In some implementations, the channel layer can include a doped portion and an undoped portion.

In some implementations, the second semiconductor structure 420 in each memory region 422 can include a semiconductor layer 465 covering the memory stack 460 and in contact with the plurality of channel structures. In some implementations, semiconductor layer 465 can include doped polysilicon and be in contact with the doped portion of the channel layers. In some implementations, the semiconductor layer 465 and the doped portion of the channel layers can include an N-type dopant. The semiconductor layer 465 can function as a common source line of the channel structures of the NAND memory strings.

As shown in FIG. 4, the second semiconductor structure 420 in the spacer regions 424 can include a dielectric stack 470. The dielectric stack 470 can include a plurality of pairs each including a stack sacrificial layer and the stack dielectric layer. In some implementations, the stack sacrificial layers can include any suitable dielectric materials different from the stack dielectric layers (i.e., silicon nitride, etc.). The interleaved stack sacrificial layers and stack dielectric layers are part of dielectric stack 470. In some implementations, the number of the pairs of stack sacrificial layers and stack dielectric layers in the dielectric stack 470 is the same as the number of the pairs of stack conductive layers and stack dielectric layers in the memory stack 460. In some implementations, the second semiconductor structure 420 in the spacer regions 424 may further include periphery contact structures (not shown) through the dielectric stack 470. In some implementations, the periphery contact structures can be coupled with transistors 436 of the periphery circuits through the first and second interconnect layers and the first and second bonding layers.

Instead of the front side interconnection structures, 3D memory device 400 can include a patterned conductive layer 480 including backside interconnection structures 485 (also referred to as backside contact structures or backside contact pads) above and coupled with the semiconductor layer 465, as shown in FIG. 4. In some implementations, patterned conductive layer 480 can be formed by any suitable BEOL method. The backside interconnection structures 485 are electrically connected to the channel layer of channel structures through doped semiconductor layer 465. The backside interconnection structures 485 can include any suitable types of contact structures and/or pads. In some implementations, the backside interconnection structures 485 can include a VIA contact, a wall-shaped contact extending laterally, one or more conductive layers, such as a metal layer (e.g., W, Co, Cu, or Al) or a silicide layer surrounded by an adhesive layer (e.g., titanium nitride (TiN)), etc.

In some implementations, a first insulating layer 472 can be formed in the memory regions 422 and the spacer regions 424 to cover the semiconductor layer 465, the memory stack 460, and the dielectric stack 470. Openings can be formed in the first insulating layer 472 to expose portions of the semiconductor layer 465. An adhesive layer 482 can be formed on the first insulating layer 472 and in the openings to be in contact with the semiconductor layer 465. The patterned conductive layer 480 can be formed on the adhesive layer 482. As shown in FIG. 4, in memory regions 422, the patterned conductive layer 480 can include backside interconnection structures 485. Each backside interconnection structure 485 can include a via structure extending through the first insulating layer 472 to be in electrical contact with the semiconductor layer 465. In spacer regions 424, the patterned conductive layer 480 can include dummy interconnection structures 488 which are above the first insulating layer 472. A second insulating layer 474 and a protection layer 490 can be formed to cover the patterned conductive layer 480.

Although an exemplary 3D memory device 400 is shown in FIG. 4, it is understood that by varying the relative positions of first and second semiconductor structures 410 and 420, the usage of various interconnects, contact structures, and/or the pad-out locations (e.g., through first semiconductor structure 410 and/or second semiconductor structure 420), any other suitable architectures of 3D memory devices may be applicable in the present disclosure without further detailed elaboration.

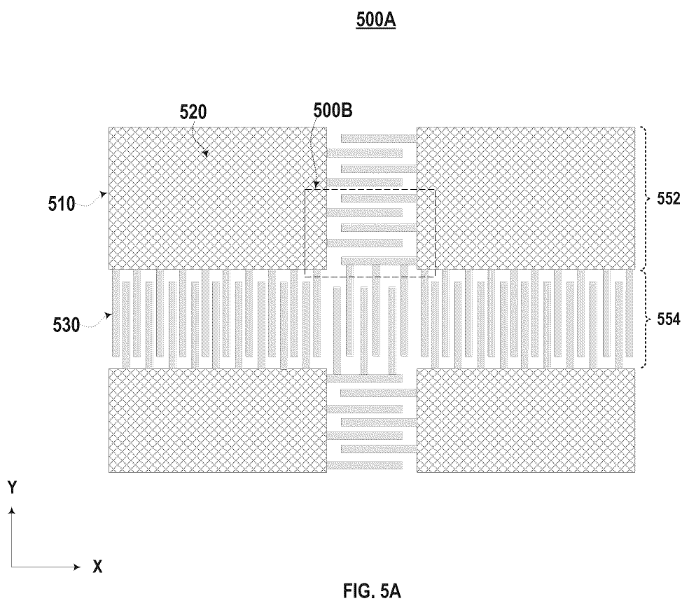

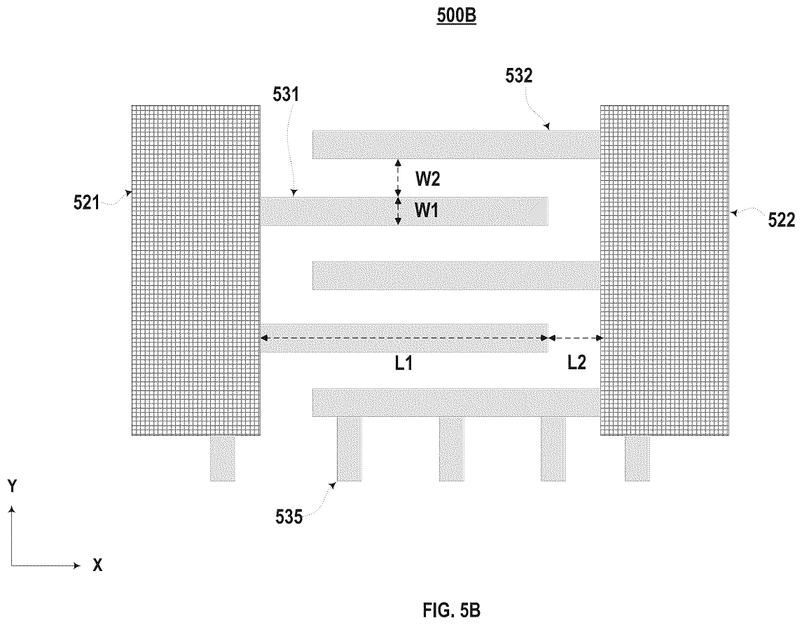

FIG. 5A illustrates a schematic diagram of an exemplary 3D memory die 500A in a top view, according to various aspects of the present disclosure. FIG. 5B illustrates a schematic diagram of a portion 500B of 3D memory die 500A in an enlarged top view, according to various aspects of the present disclosure. It is noted that, a 3D memory die 500A of a 3D memory device can include one or more memory planes, such as four memory planes 510 as shown in FIG. 5A. Identical and concurrent operations can take place at each memory plane 510. As described above, each memory plane 510 can include a NAND memory cell array and correspond to a memory region 552. Spacer region 554 can be located between adjacent memory planes 510.

In some implementations, 3D memory die 500A can include a patterned conductive layer (e.g., the patterned conductive layer 480) including interconnection structures 520 (i.e., backside interconnection structures 485) located in the memory regions 552, and dummy interconnection structures 530 (i.e., dummy interconnection structures 488) located in the spacer region 554. It is noted that, the backside interconnection structures 520 can include any suitable types of contact structures and/or pads with any suitable shapes, which are illustrated by using a rhombic grid network pattern for simplicity. As shown in FIGS. 5A and 5B, each dummy interconnection structure 530 can extend along a first lateral direction (e.g., x-direction or y-direction) and comprising a first end in contact with the backside interconnection structures 520 and a second end without in contact with the backside interconnection structures 520.

In some implementations, the dummy interconnection structures 530 can be arranged in a staggered manner. Specifically, as shown in FIG. 5B, the dummy interconnection structures 530 can comprise first dummy interconnection structures 531 in contact with first interconnection structures 521 in a first memory region and having a first distance L2 from second interconnection structures 522 in a second memory region adjacent to the first memory region. The dummy interconnection structures 530 can further comprise second dummy interconnection structures 532 in contact with the second interconnection structures 522 in a second memory region and having the first distance L2 from the first interconnection structures 521 in the first memory region.

As shown in FIG. 5B, in some implementations, the first dummy interconnection structures 531 and the second dummy interconnection structures 532 are positioned alternatively along a second lateral direction different from the first lateral direction. A first radio between a length L1 of one first dummy interconnection structure 531 and the first distance L2 is in a range between about 1 and about 100. A second radio between a width W1 of one first dummy interconnection structure 531 and a second distance W2 from the one first dummy interconnection structure 531 to an adjacent second dummy interconnection structure 532 is in a range between about 1 and about 50.

As shown in FIG. 5B, in some implementations, the dummy interconnection structures 530 can include a central dummy interconnection structure 535 located in a central spacer region between four adjacent memory regions 552, and comprising a first branch extending along the first lateral direction and a second branch extending along the second lateral direction. It is noted that the first dummy interconnection structures 531 and the second dummy interconnection structures 532 are not in contact with each other. For example, the first dummy interconnection structures 531 and the second dummy interconnection structures 532 cannot form an X shape.

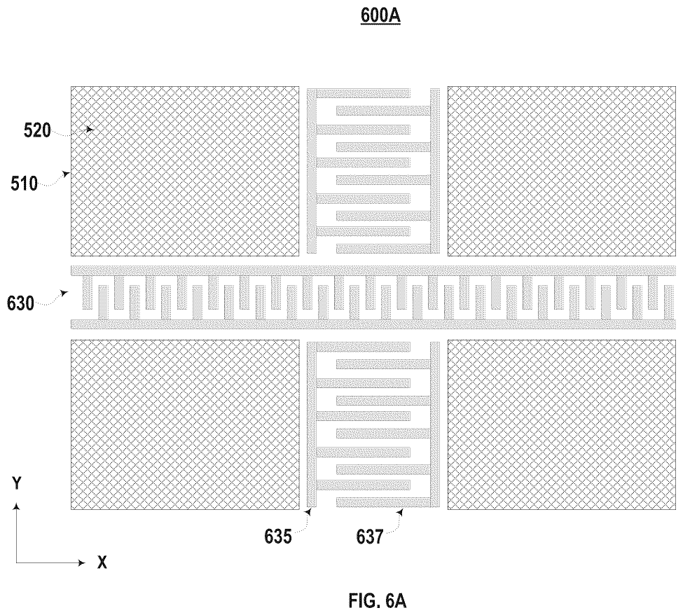

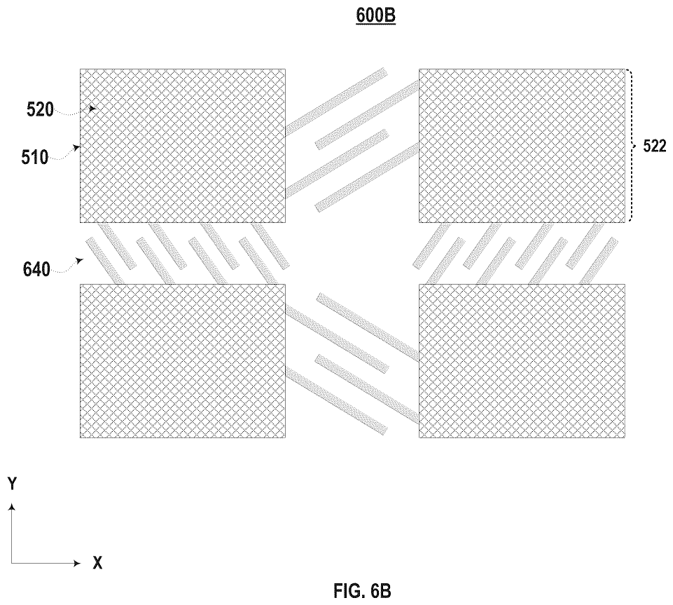

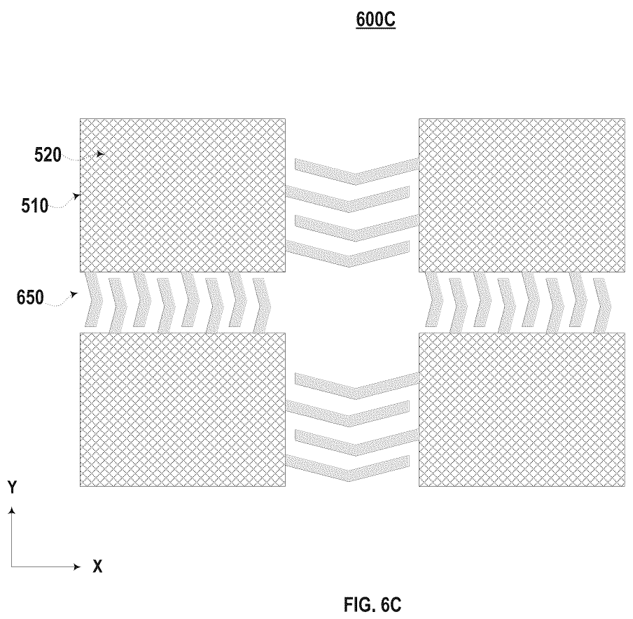

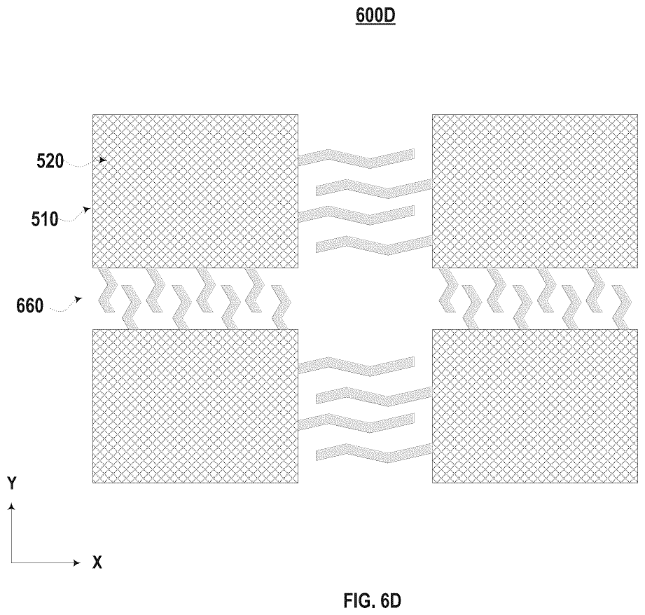

FIGS. 6A-6D illustrate schematic diagrams of exemplary 3D memory dies 600A/600B/600C/600D in a top view, according to various aspects of the present disclosure. As shown in FIG. 6A, in some implementations, each dummy interconnection structure 630 comprises a first branch 635 extending along a first lateral direction and a plurality of second branches 637 each extending along a second lateral direction different from the first lateral direction. The second branches 637 of two adjacent dummy interconnection structures 630 are positioned alternatively along the first lateral direction. As shown in FIG. 6B, in some implementations, an angle between each dummy interconnection structure 640 and an edge of one memory region 552 in a lateral plane is less than 90 degrees. As shown in FIG. 6C, in some implementations, each dummy interconnection structure 650 comprises a first section extending along a first lateral direction and a second section extending along a second lateral direction different from the first lateral direction. An angle between the first section and the second section is larger than 90 degrees. As shown in FIG. 6D, in some implementations, each dummy interconnection structure 660 comprises a first section and a third section each extending along a first lateral direction, and a second section between the first section and the third section, and extending along a second lateral direction different from the lateral first direction.

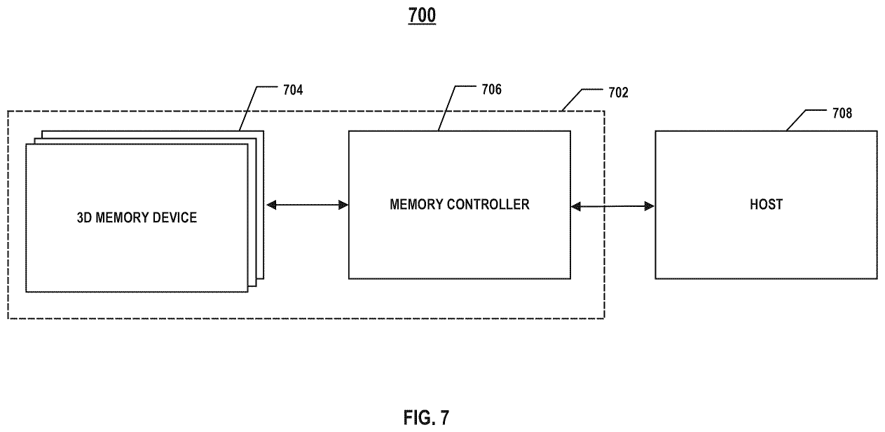

FIG. 7 illustrates a block diagram of an exemplary system 700 having a 3D memory device, according to some aspects of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more 3D memory devices 704 and a memory controller 706. Host 708 can be a processor of an electronic device, such as a central processing unit (CPU), or a system-on-chip (SoC), such as an application processor (AP). Host 708 can be configured to send or receive data to or from 3D memory devices 704.

3D memory device 704 can be any 3D memory devices disclosed herein, such as 3D memory device 400 shown in FIG. 4. In some implementations, each 3D memory device 704 includes a NAND Flash memory. Consistent with the scope of the present disclosure, the channel layer of 3D memory device 704 can be partially doped such that part of the channel layer that forms the source contact is highly doped to lower the potential barrier while leaving another part of the channel layer that forms the memory cells remaining undoped or lowly doped. One end of each channel structure of 3D memory device 704 can be opened from the backside to expose the doped part of the respective channel layer. 3D memory device 704 can further include a doped semiconductor layer electrically connecting the exposed doped parts of the channel layers to further reduce the contact resistance and sheet resistance. Moreover, 3D memory device 704 can include a composite dielectric film having a gate dielectric portion that faces the source select gate line(s). The gate dielectric portion can be free of silicon nitride (e.g., including only silicon oxide) and act as the gate dielectric of the SSG transistor. As a result, the electric performance of 3D memory device 704 can be improved, which in turn improves the performance of memory system 702 and system 700, e.g., achieving higher operation speed.

Memory controller 706 (a.k.a., a controller circuit) is coupled to 3D memory device 704 and host 708 and is configured to control 3D memory device 704, according to some implementations. Memory controller 706 can manage the data stored in 3D memory device 704 and communicate with host 708. In some implementations, memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704. Memory controller 706 can communicate with an external device (e.g., host 708) according to a particular communication protocol. For example, memory controller 706 may communicate with the external device through at least one of various interface protocols, such as a USB protocol, an MMC protocol, a periphery component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

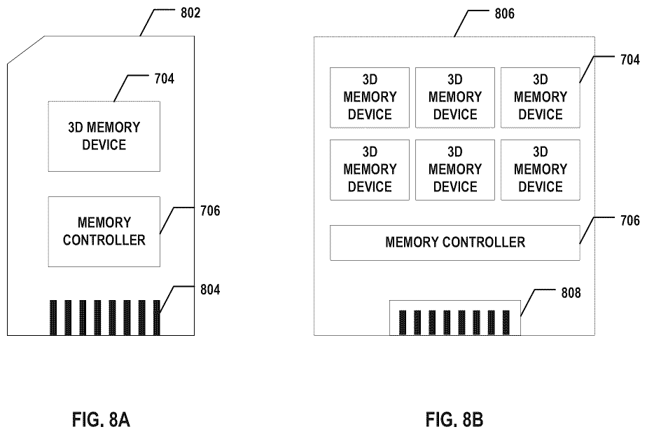

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 8A, memory controller 706 and a single 3D memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 802 can further include a memory card connector 804 electrically coupling memory card 802 with a host (e.g., host 708 in FIG. 7). In another example as shown in FIG. 8B, memory controller 706 and multiple 3D memory devices 704 may be integrated into an SSD 806. SSD 806 can further include an SSD connector 808 electrically coupling SSD 806 with a host (e.g., host 708 in FIG. 7). In some implementations, the storage capacity and/or the operation speed of SSD 806 is greater than those of memory card 802.

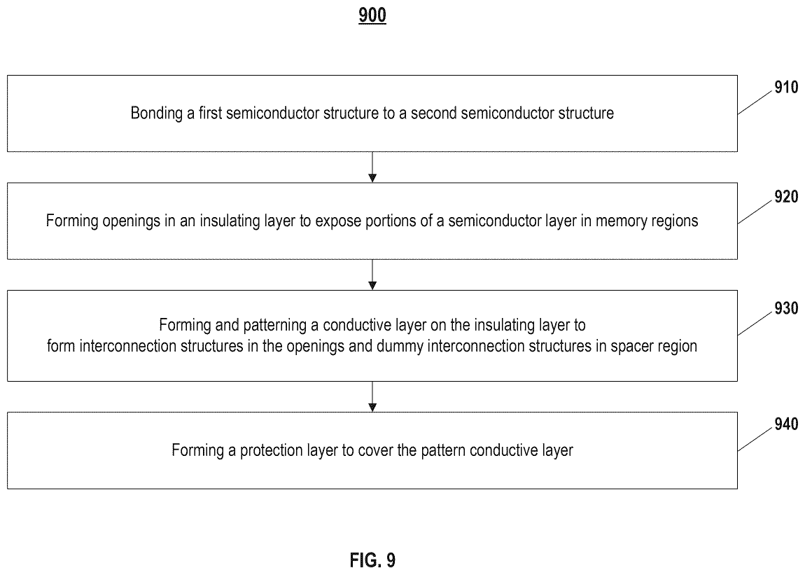

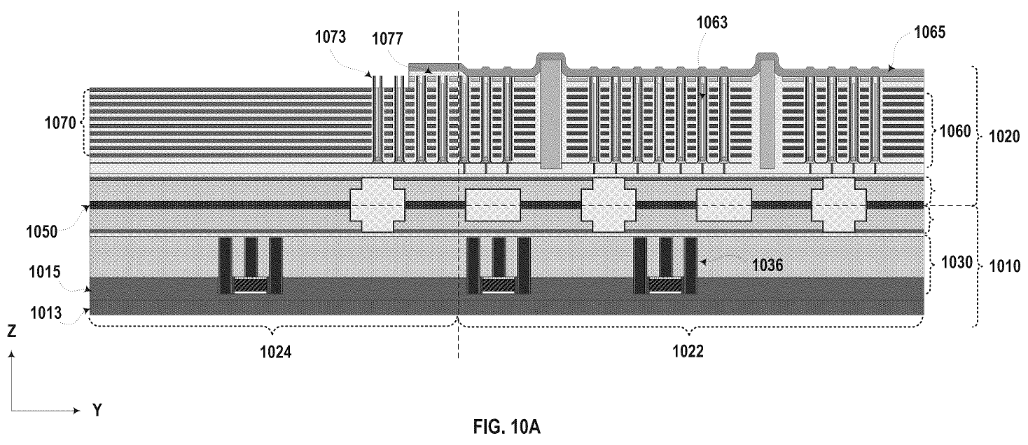

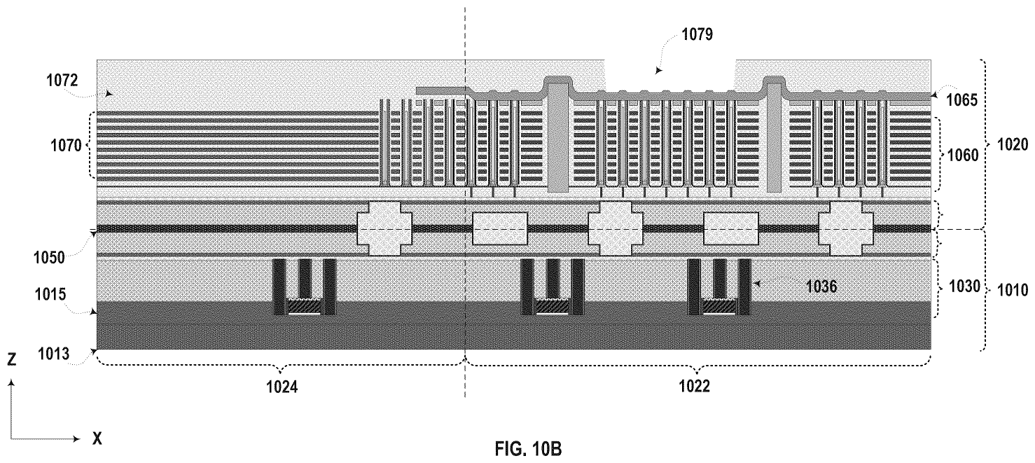

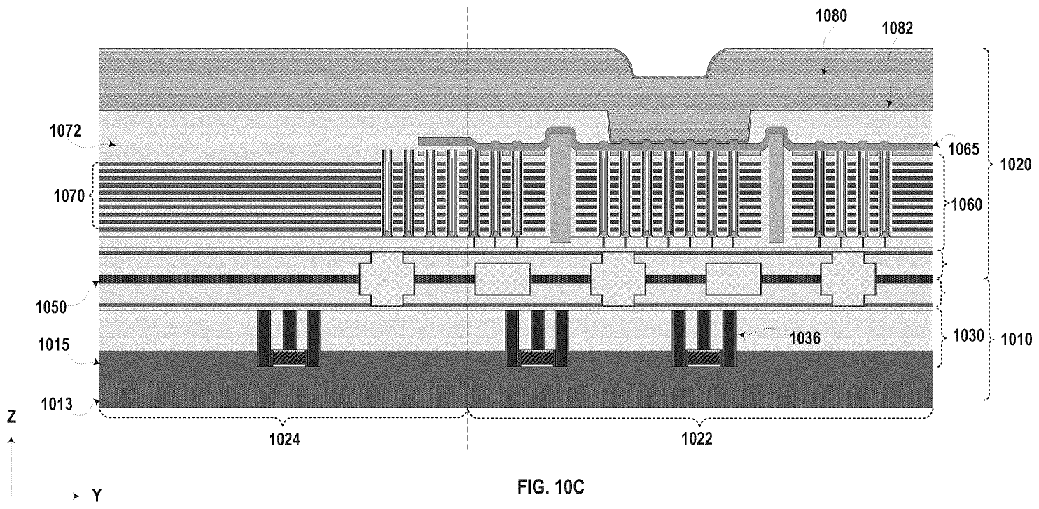

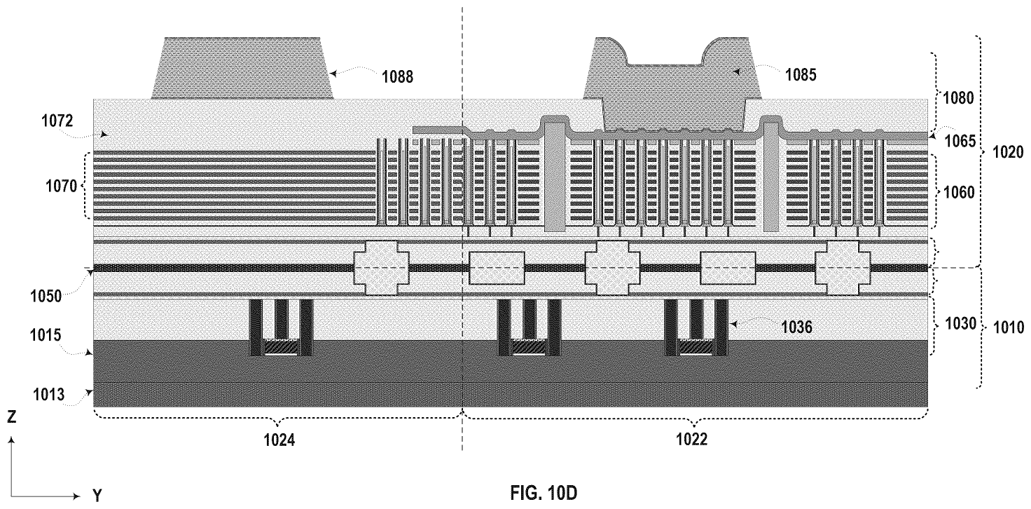

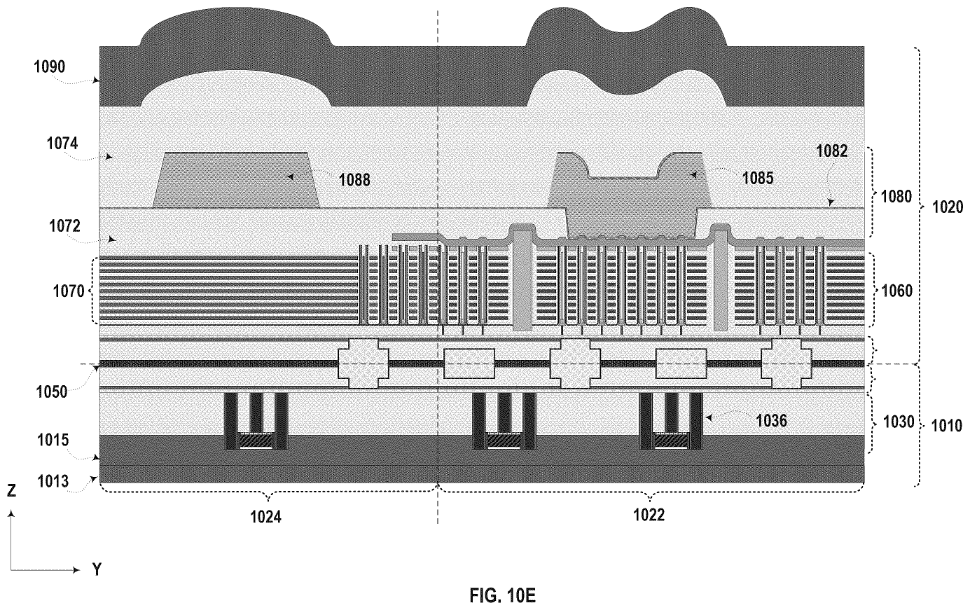

Referring to FIG. 9, a flow diagram of an exemplary method 900 for forming a 3D memory device is illustrated in accordance with some implementations of the present disclosure. It should be understood that, the operations shown in FIG. 9 are not exhaustive and that other operations can be performed as well before, after, or between any of the illustrated operations. Further, some of the operations may be performed simultaneously, or in a different order than shown in FIG. 9. FIGS. 10A-10E illustrate schematic cross-sectional views of an exemplary 3D memory device at certain fabricating stages of method 900 shown in FIG. 9 according to some implementations of the present disclosure.

Referring to FIG. 9, method 900 can start at operation 910, in which a first semiconductor structure and a second semiconductor structure can be formed, and the first semiconductor structure can be bonded to the second semiconductor structure. In some implementations, forming the first semiconductor structure can include forming a plurality of memory regions each comprising a memory stack and a plurality of channel structures vertically extending through the memory stack, and forming a spacer region between the plurality of memory regions and comprising dielectric stack portions located between adjacent memory stacks. In some implementations, forming the second semiconductor structure can include forming a plurality of transistors.

FIG. 10A illustrates a schematic cross-sectional view of the 3D semiconductor structure after operation 910, according to some implementations of the present disclosure. As shown in FIG. 10A, the first semiconductor structure 1010 and the second semiconductor structure 1020 are bonded together at a bonding interface 1050 therebetween, according to some implementations.

As shown in FIG. 10A, forming the first semiconductor structure 1010 can include forming a device layer 1030 on a semiconductor layer 1015 and a substrate 1013. In some implementations, forming the device layer 1030 comprises forming a plurality of transistors 1036 on the semiconductor layer 1015. In some implementations, isolation regions (e.g., shallow trench isolations (STIs), not shown) and doped regions (e.g., source regions and drain regions of the transistors) can be formed in semiconductor layer 1015. In some implementations, forming the first semiconductor structure 1010 can include forming a first interconnect layer (not shown) and a first bonding layer. The first interconnect layer can include a plurality of interconnects, and the first bonding layer can include a plurality of bonding contact structures. The first interconnect layer and the first bonding layer can be formed by any suitable MEOL/BEOL processes.

In some implementations, forming the second semiconductor structure 1020 can include forming memory regions 1022 including a memory stack 1060, and spacer regions 1024 including a dielectric stack 1070. In some implementations, forming the second semiconductor structure 1020 can include forming a plurality of channel structures 1063 vertically extending through the memory stack 1060. Specifically, forming the second semiconductor structure 1020 can include forming a dielectric stack 1070 including alternating dielectric layers and sacrificial layers, forming the plurality of channel structures 1063 vertically extending through the dielectric stack in the plurality of memory regions 1022, and replacing portions of the sacrificial layers in the plurality of memory regions 1022 with conductive layers to convert the dielectric stack 1070 in the plurality of memory regions 1022 into the plurality of memory stacks 1060. The remaining portions of the dielectric stack 1070 are located in the spacer region 1024 between the plurality of memory regions 1022.

In some implementations, forming the second semiconductor structure 1020 can further include forming a semiconductor layer 1065 in the memory regions 1022 covering the memory stacks 1060 and in contact with ends (e.g., upper ends) of the plurality of channel structures. In some implementations, the semiconductor layer 465 can be doped with an N-type dopant. In some implementations, forming the second semiconductor structure 1020 can further include forming a plurality of dummy channel structures 1073 vertically extending through the dielectric stack 1070 in the spacer region 1024, and forming a block layer 1077 on the dummy channel structures 1073 in the spacer region 1024. In some implementations, the semiconductor layer 1065 extends into the spacer region 1024, and is separated from the dummy channel structures 1073 by the block layer 1077.

In some implementations, forming the second semiconductor structure 1020 further includes forming a second interconnection layer (not shown) in contact with the ends of the plurality of channel structures, and forming a second bonding layer coupled with the second interconnection layer. The second interconnect layer can include a plurality of interconnects, and the second bonding layer can include a plurality of bonding contact structures. The second interconnect layer and the second bonding layer can be formed by any suitable MEOL/BEOL processes.

In some implementations, the second semiconductor structure 1020 can be bonded to the first semiconductor structure 1010 at bonding interface 1050. The first semiconductor structure 1010 and the second semiconductor structure 1020 can be bonded in a face-to-face manner. The bonding can include hybrid bonding. In some implementations, a treatment process, e.g., a plasma treatment, a wet treatment, and/or a thermal treatment, is applied to the bonding surfaces of first semiconductor structure 1010 and second semiconductor structure 1020 prior to the bonding. After the bonding, corresponding bonding contact structures in the first and second bonding layers are aligned and in contact with one another, such that the channel structure and the transistors 1036 can be electrically connected.

Referring back to FIG. 9, method 900 proceeds to operation 920, in which an insulating layer can be formed in the space region and the plurality of memory regions to cover the dielectric stack and the semiconductor layer, and openings can be formed in the insulating layer in the memory regions to expose portions of the semiconductor layer. FIG. 10B illustrates a schematic cross-sectional view of the 3D semiconductor structure after operation 920, according to some implementations of the present disclosure. As shown in FIG. 10B, a first insulating layer 1072 can be formed in the spacer region 1024 and the plurality of memory regions 1022 to cover the dielectric stack 1070 and the semiconductor layer 1065. The first insulating layer 1072 can be formed by any suitable deposition process. Openings 1079 can be formed in the first insulating layer 1072 by any suitable etching process to expose portions of the semiconductor layer 1065.

Referring back to FIG. 9, method 900 proceeds to operation 930, in which a conductive layer can be formed on the insulating layer and in the openings, and the conductive layer can be patterned to form interconnection structures in the memory regions and in contact with ends of the plurality of channel structures, and form dummy interconnection structures on the dielectric stack in the spacer region. FIGS. 10C and 10D illustrate schematic cross-sectional views of the 3D semiconductor structure at certain stages of operation 930, according to some implementations of the present disclosure. As shown in FIG. 10C, an adhesive layer 1082 can be formed on the first insulating layer 1072 and in the openings 1079, and a conductive layer 1080 can be formed on the adhesive layer 1082. The adhesive layer 1082 and the conductive layer 1080 can be formed by any suitable deposition process.

As shown in FIG. 10D, the conductive layer 1080 can be patterned to form the interconnection structures 1085 in the memory regions 1022 and the dummy interconnection structures 1088 in the spacer region 1024. In some implementations, each interconnection structure 1085 can include a via structure penetrating the first insulating layer 1072 and be coupled with the dummy channel structures 1073. In various implementations, the dummy interconnection structures 1088 can have different shapes as described above in connection with FIGS. 5A-5B and 6A-6D.

In some implementations, patterning the conductive layer 1080 comprises forming each dummy interconnection structure 1088 extending along a lateral direction and comprising a first end in contact with the interconnection structures 1085 and a second end without in contact with the interconnection structures 1085.

In some implementations, patterning the conductive layer 1080 comprises forming first dummy interconnection structures 1088 in contact with first interconnection structures 1085 in a first memory region and having a first distance from second interconnection structures 1085 in a second memory region adjacent to the first memory region, and forming second dummy interconnection structures 1088 in contact with the second interconnection structures 1085 in a second memory region and having the first distance from the first interconnection structures 1085 in the first memory region. The first dummy interconnection structures 1088 and the second dummy interconnection structures 1088 are positioned alternatively.

In some implementations, patterning the conductive layer 1080 comprises forming the dummy interconnection structures 1088 in a corner spacer region between four plurality of memory regions each comprising a first branch extending along a first lateral direction and a second branch extending along a second lateral direction different from the first lateral direction.

In some implementations, patterning the conductive layer 1080 comprises forming each dummy interconnection structure 1088 comprising a first branch extending along a first lateral direction and a plurality of second branches each extending along a second lateral direction different from the first lateral direction. The second branches of two adjacent dummy interconnection structures 1088 are positioned alternatively along the first lateral direction.

In some implementations, patterning the conductive layer 1080 comprises forming the angle between each dummy interconnection structure 1088 and an edge of one memory region 1022 in a lateral plane less than 90 degrees.

In some implementations, patterning the conductive layer 1080 comprises forming each dummy interconnection structure 1088 comprising a first section extending along a first lateral direction and a second section extending along a second lateral direction different from the first lateral direction. The angle between the first section and the second section is larger than 90 degrees.

In some implementations, patterning the conductive layer 1080 comprises forming each dummy interconnection structure 1088 comprising a first section and a third section each extending along a first lateral direction, and a second section between the first section and the third section, and extending along a second lateral direction different from the first lateral direction.

Referring back to FIG. 9, method 900 proceeds to operation 940, in which a protection layer can be formed to cover the pattern conductive layer. FIG. 10E illustrates a schematic cross-sectional view of the 3D semiconductor structure after operation 940, according to some implementations of the present disclosure. As shown in FIG. 10E, a second insulating layer 1074 can be formed to cover the pattern conductive layer 1080 including the adhesive layer 1082, the dummy interconnection structures 1088 and the interconnection structures 1085. A protection layer 1090 can be formed to cover the second insulating layer 1074. Protection layer 1090 can be a polymer film including any suitable nanoconfinement of polymers configured to prevent scratching of or damage to the formed 3D semiconductor structure.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising:
a plurality of memory regions each comprising a memory stack and a plurality of channel structures vertically extending through the memory stack;
a spacer region between the plurality of memory regions, comprising a dielectric stack located between adjacent memory stacks; and
a patterned conductive layer on the memory stacks and the dielectric stack, comprising:
interconnection structures in the memory regions and coupled with the plurality of channel structures, and
dummy interconnection structures on the dielectric stack in the spacer region and arranged in a staggered manner.

2. The semiconductor device of claim 1, further comprising:
a semiconductor layer in the memory regions covering the memory stacks and in contact with the plurality of channel structures;
wherein each interconnection structure includes a via structure extending through an insulating layer and in contact with the semiconductor layer, and each dummy interconnection structure is above the insulating layer.

3. The semiconductor device of claim 1, wherein each dummy interconnection structure extends along a lateral direction and comprises a first end in contact with the interconnection structures and a second end without in contact with the interconnection structures.

4. The semiconductor device of claim 3, wherein the dummy interconnection structures comprise:
first dummy interconnection structures in contact with first interconnection structures in a first memory region and having a first distance from second interconnection structures in a second memory region adjacent to the first memory region; and
second dummy interconnection structures in contact with the second interconnection structures in a second memory region and having the first distance from the first interconnection structures in the first memory region;
wherein the first dummy interconnection structures and the second dummy interconnection structures are positioned alternatively.

5. The semiconductor device of claim 4, wherein:
a first radio between a length of one first dummy interconnection structure and the first distance is in a range between about 1 and about 100; and
a second radio between a width of one first dummy interconnection structure and a second distance from the one first dummy interconnection structure to an adjacent second dummy interconnection structure is in a range between about 1 and about 50.

6. The semiconductor device of claim 2, wherein the dummy interconnection structures comprise:
a central dummy interconnection structure located in a central spacer region between four adjacent memory regions, and comprising a first branch extending along a first lateral direction and a second branch extending along a second lateral direction different from the first lateral direction.

7. The semiconductor device of claim 1, wherein:
each dummy interconnection structure comprises a first branch extending along a first lateral direction and a plurality of second branches each extending along a second lateral direction different from the first lateral direction; and
the second branches of two adjacent dummy interconnection structures are positioned alternatively along the first lateral direction.

8. The semiconductor device of claim 1, wherein:
an angle between each dummy interconnection structure and an edge of one memory region in a lateral plane is less than 90 degrees.

9. The semiconductor device of claim 1, wherein:
each dummy interconnection structure comprises a first section extending along a first lateral direction and a second section extending along a second lateral direction different from the first lateral direction; and
an angle between the first section and the second section is larger than 90 degrees.

10. The semiconductor device of claim 1, wherein each dummy interconnection structure comprises:
a first section and a third section each extending along a first lateral direction; and
a second section between the first section and the third section, and extending along a second lateral direction different from the lateral first direction.

11. A semiconductor device, comprising:
a first memory plane comprising:
a first memory stack,
first channel structures vertically extending through the first memory stack, and
first interconnection structures on the first memory stack and coupled with the first channel structures;
a second memory plane located at a lateral side of the first memory plane, comprising:
a second memory stack,
second channel structures vertically extending through the second memory stack, and
second interconnection structures on the second memory stack and coupled with the first channel structures;
a spacer region between the first memory plane and the second memory planes, comprising:
a dielectric stack located laterally between the first memory stack and the second memory stack,
first dummy interconnection structures extending along a first lateral direction on the dielectric stack and in contact with the first interconnection structures, and
second dummy interconnection structures along the first lateral direction on the dielectric stack and in contact with the second interconnection structure,
wherein the first dummy interconnection structures and the second dummy interconnection structures are alternatively arranged along a second lateral direction.

12. A method of forming a semiconductor device, comprising:
forming a plurality of memory regions each comprising a memory stack and a plurality of channel structures vertically extending through the memory stack, and forming a spacer region between the plurality of memory regions and comprising dielectric stack portions located between adjacent memory stacks; and
forming a patterned conductive layer on the memory stacks and the dielectric stack, comprising:
forming interconnection structures in the memory regions and coupled with the plurality of channel structures, and
forming dummy interconnection structures on the dielectric stack in the spacer region and arranged in a staggered manner.

13. The method of claim 12, further comprising:
forming a semiconductor layer in the memory regions covering the memory stacks and in contact with first ends of the plurality of channel structures; and
forming an insulating layer in the space region and the plurality of memory regions to cover the dielectric stack portions and the semiconductor layer.

14. The method of claim 13, wherein forming the patterned conductive layer comprises:
forming openings in the insulating layer to expose the semiconductor layer;
forming a conductive layer on the insulating layer and in the openings to be in contact with the semiconductor layer; and
patterning the conductive layer to form the patterned conductive layer.

15. The method of claim 14, further comprising:
forming a dielectric stack including alternating dielectric layers and sacrificial layers;
forming the plurality of channel structures vertically extending through the dielectric stack in the plurality of memory regions;
replacing portions of the sacrificial layers in the plurality of memory regions with conductive layers to convert the dielectric stack in the plurality of memory regions into the memory stacks; and
remaining the portions of the dielectric stack in the spacer region between the plurality of memory regions.

16. The method of claim 15, further comprising:
forming a plurality of dummy channel structures vertically extending through the dielectric stack in the spacer region; and
forming a block layer on the dummy channel structures in the spacer region;
wherein the semiconductor layer extends into the spacer region and is separated from the dummy channel structures by the block layer.

17. The method of claim 15, wherein patterning the conductive layer comprises:
forming each dummy interconnection structure extending along a lateral direction and comprising a first end in contact with the interconnection structures and a second end without in contact with the interconnection structures.

18. The method of claim 15, wherein patterning the conductive layer comprises:
forming first dummy interconnection structures in contact with first interconnection structures in a first memory region and having a first distance from second interconnection structures in a second memory region adjacent to the first memory region; and
forming second dummy interconnection structures in contact with the second interconnection structures in a second memory region and having the first distance from the first interconnection structures in the first memory region;
wherein the first dummy interconnection structures and the second dummy interconnection structures are positioned alternatively.

19. The method of claim 15, wherein patterning the conductive layer comprises:
forming each dummy interconnection structure comprising a first branch extending along a first lateral direction and a plurality of second branches each extending along a second lateral direction different from the first lateral direction;
wherein the second branches of two adjacent dummy interconnection structures are positioned alternatively along the first lateral direction.

20. The method of claim 15, wherein patterning the conductive layer comprises:
forming each dummy interconnection structure comprising a first section extending along a first lateral direction and a second section extending along a second lateral direction different from the first lateral direction;
wherein an angle between the first section and the second section is larger than 90 degrees.
